(19) United States
(12) Patent Application Publication
(10) Pub. No.: US 2008/0292115 A1
(43) Pub. Date: Nov. 27, 2008

(54) APPARATUS AND METHOD FOR ADJUSTING SOUND VOLUME

(75) Inventors: LIN-KUN DING, Shenzhen (CN); XIANG-PING ZHOU, Shenzhen (CN); SHIH-FANG WONG, Tu-Cheng (TW); TSUNG-JEN CHUANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-cheng (TW)

(21) Appl. No.: 11/875,957

(22) Filed: Oct. 22, 2007

(30) Foreign Application Priority Data
May 22, 2007 (CN) 200710200667.6

(51) Int. Cl. H03G 7/00

(52) U.S. Cl. 381/104

(57) ABSTRACT

An apparatus for adjusting a sound volume includes an ultrasonic transreceiver for transmitting an ultrasonic signal and receiving a reflected ultrasonic signal reflected back from an object, and a volume module for adjusting the sound volume based on a time from transmitting the ultrasonic signal to receiving the reflected ultrasonic signal that has a different frequency from the ultrasonic signal.

### BACKGROUND

1. Field of the Invention

This invention generally relates to electronic sound devices, and particularly to an apparatus and method for adjusting sound volume automatically.

2. Description of Related Art

Nowadays, electronic sound devices, such as television sets, multimedia computers, portable DVD players, and AV receivers are widely used for a variety of applications. In order to satisfy different requirements of sound volume in different environments, an electronic sound device usually includes an apparatus for adjusting the sound volume.

Generally, there are two ways to adjust the sound volume. A first way is by pressing keys or turning a knob disposed on a panel of the electronic sound device. A second way is to use a remote control to send electromagnetic signals to the electronic sound device so as to adjust the sound volume.

Although the second way is much more convenient than the first way, the user must still operate the remote control. As the distance between the user and the electronic sound device varies, the user may wish to adjust the volume. However, the user may be performing a task that involved the use of both hands and cannot adjust the sound volume without stopping the task. As such, this method is inconvenient and may not satisfy all users' requirements.

Therefore, an improved method and apparatus for adjusting the sound volume automatically are desired.

### SUMMARY

An apparatus for adjusting a sound volume includes a timer for measuring a time from transmitting an ultrasonic signal to receiving a reflected ultrasonic signal reflected back from an object. The reflected ultrasonic signal has a different frequency from the ultrasonic signal. The apparatus further includes a distance calculating unit for calculating a distance between the object and the apparatus based on the time and an adjust unit for adjusting the sound volume based on the distance.

An apparatus for adjusting a sound volume includes an ultrasonic transreceiver for transmitting an ultrasonic signal and receiving a reflected ultrasonic signal reflected back from an object, and a volume module for adjusting the sound volume based on a time from transmitting the ultrasonic signal to receiving the reflected ultrasonic signal that has a different frequency from the ultrasonic signal.

A method for adjusting a sound volume of an apparatus includes: measuring a time from transmitting an ultrasonic signal to receiving a reflected ultrasonic signal reflected back from an object if there is a frequency difference between the ultrasonic signal and the reflected ultrasonic signal; and adjusting the sound volume based on the time.

Other advantages and novel features will become more apparent from the following detailed description of preferred embodiments when taken in conjunction with the accompanying drawings.

### BRIEF DESCRIPTION OF THE DRAWINGS

Many aspects of the apparatus and method can be better understood with reference to the following drawings. The components in the drawings are not necessarily to scale, the emphasis instead being placed upon clearly illustrating the principles of the present apparatus and method. Moreover, in the drawings, like reference numerals designate corresponding parts throughout the several views.

FIG. 1 is a schematic diagram of an automatic sound volume apparatus in accordance with an exemplary embodiment.

FIG. 2 is a table illustrating relationships between distances and sound volume values.

FIG. 3 is a procedure of a method for adjusting sound volume.

### DETAILED DESCRIPTION OF THE EMBODIMENTS

Reference will now be made to the drawings to describe a preferred embodiment of an automatic sound volume apparatus and method for adjusting sound volume.

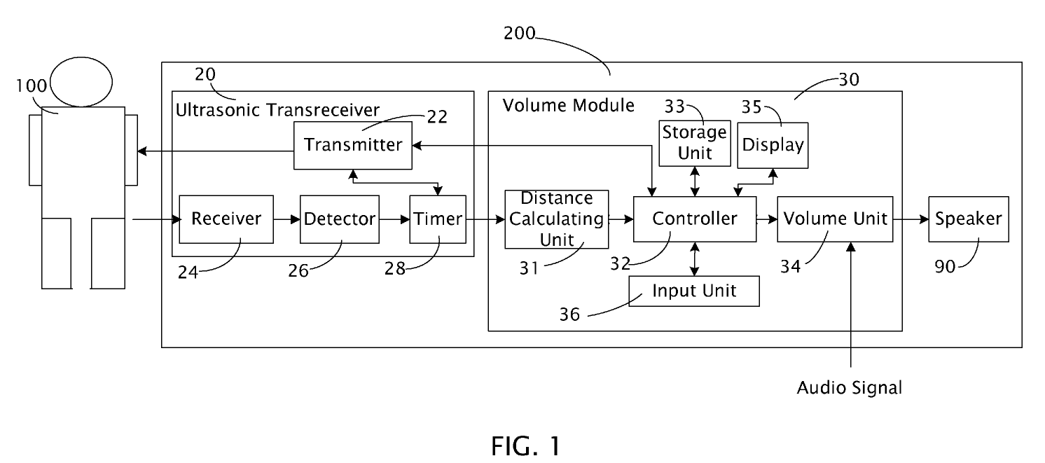

Referring to FIG. 1, a block diagram of an automatic sound volume apparatus 200 (hereinafter referred to as apparatus 200) for adjusting sound volume is illustrated. The apparatus 200 includes an ultrasonic transreceiver 20, a volume module 30, and a speaker 40. The ultrasonic transreceiver 20 is configured for transmitting an ultrasonic signal (hereinafter referred to as outputted signal) and receiving a reflected ultrasonic signal (hereinafter referred to as reflected signal) reflected back from an object, such as a user 100. The transreceiver 20 is further configured for measuring a time from transmitting the outputted signal to receiving the reflected signal that has a different frequency from the outputted signal. The volume module 30 is connected to the ultrasonic transreceiver 20 for adjusting a sound volume of the speaker 40 based on the time.

The ultrasonic transreceiver 20 includes a transmitter 22, a receiver 24, a detector 26, and a timer 28.

The transmitter 22 is used for generating and transmitting the outputted signal. The receiver 24 is configured for receiving the reflected signal reflected back from the object.

The detector 26 is connected to the receiver 24 for measuring a frequency of the reflected signal to determine whether the reflected signal is reflected back from a moving object (e.g. the user 100). According to the Doppler Effect, when there is a change of frequency between the outputted signal and the reflected signal, this means that the user 100 is moving relative to the apparatus 200. More precisely, if the frequency of the reflected signal (hereinafter referred to as “reflected frequency”) is higher than the frequency of the outputted signal (hereinafter referred to as “outputted frequency”), this means that the user 100 is moving towards the apparatus 200. Accordingly, if the reflected frequency is lower than the outputted frequency, this means that the user 100 is moving away from the apparatus 200.

At the time of transmitting the outputted signal, the timer 28 starts to measure the time from transmitting the outputted signal to receiving the reflected signal that has the different frequency from the outputted signal. If the detector 26 measures that the reflected frequency is different from the outputted frequency, the detector 26 transmits a signal to the timer 28. After receiving the signal, the timer 28 stops. The time Δt is the period of time from the time of transmitting the outputted signal to the time of receiving a reflected signal that has a different frequency from the outputted signal. This time Δt is transmitted to the volume module 30.

The volume module 30 includes a distance calculating unit 31, a controller 32, a storage unit 33, a adjust unit 34, a display 35, and an input unit 36.

The distance calculating unit 31 is coupled to the timer 28 for calculating a distance S between the user 100 and the apparatus 200. The distance S is calculated by the following formula:

S=V*Δt/2

wherein V is the speed of the ultrasonic wave.

The controller 32 is connected to the distance calculating unit 31, the input unit 36, the storage unit 33, the adjust unit 34, and the display 35. The controller 32 is configured for receiving the distance S calculated by the distance calculating unit 31 and searching a sound volume value based on the distance S.

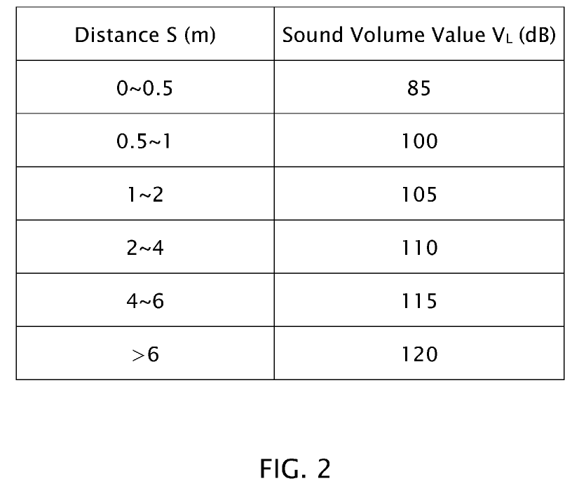

Referring also to FIG. 2, the storage unit 33 is used for storing a lookup table records relationships between sound volume values V_{L} and distances S. After receiving the distance S, the controller 32 searches for a corresponding sound volume value V_{L} corresponding to the distance S in the storage unit 33. For example, if the distance S calculated by the distance calculating unit 31 is 0.4 m, the distance S is in the range of 0˜0.5 m as illustrated in FIG. 2 and the corresponding sound volume value V_{L} corresponding to the distance S would be 85 dB. After searching for the corresponding sound volume value V_{L}, the controller 32 compares the corresponding sound volume value V_{L} with a current sound volume value to determine whether the corresponding sound volume value V_{L} is equal to the current sound volume value. If the corresponding sound volume value V_{L} is equal to the current sound volume value, the controller 32 keeps the current sound volume value unchanged. If the corresponding sound volume value V_{L} is not equal to the current sound volume value, the controller 32 generates a volume adjustment signal based on the corresponding sound volume value V_{L} and transmits the volume adjustment signal to the adjust unit 34.

The adjust unit 34 is configured for receiving the volume adjustment signal and an audio signal, and adjusting the sound volume of the audio signal based on the volume adjustment signal. Thus the sound volume of the audio signal is adjusted so as to be adaptive to the distance between the user 100 and the apparatus 200. The speaker 40 is connected to the adjust unit 34 for generating sound based on the adjusted audio signal.

The display 35 is connected to the controller 80 for displaying the sound volume, so that the user 100 is able to view the current sound volume on the display 35.

The input unit 36 is connected to the controller 32 for inputting instructions to the controller 32. The instructions can be used for, for example, but not limited to, adjusting the sound volume values V_{L} illustrated in FIG. 2.

The apparatus 200 detects the distance between the user 100 and the apparatus 200, and adjusts the sound volume according to the distance, thus the sound volume is adjusted automatically to achieve a best listening affect for the user 100.

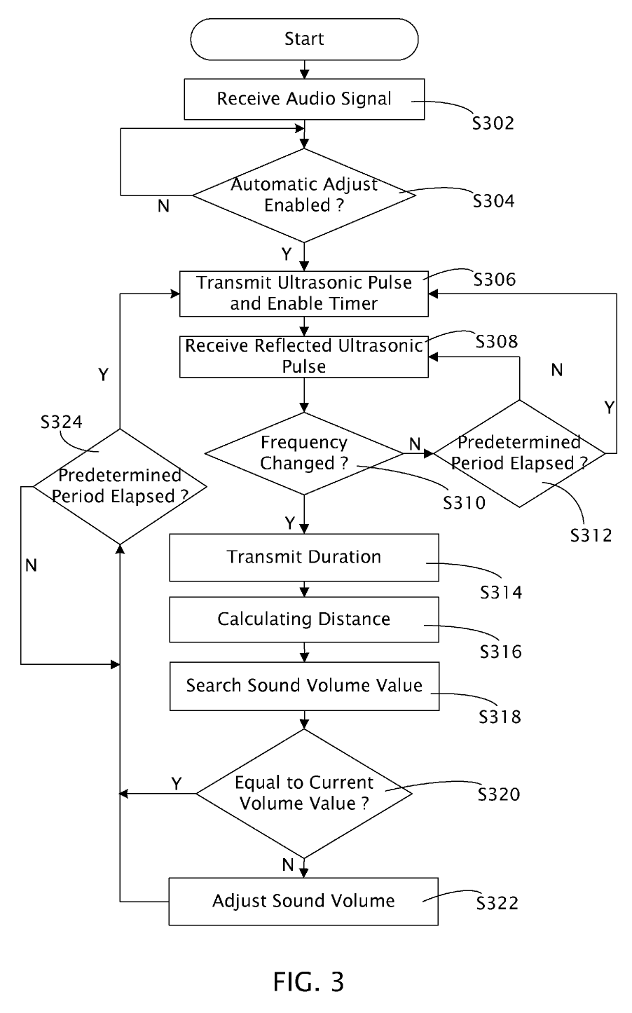

Referring to FIG. 3, a procedure of a method for adjusting the sound volume is illustrated.

First, in step S302, the apparatus 200 receives the audio signal. The audio signal can be transmitted from a MP3 player, a DVD player, etc.

In step S304, the apparatus 200 determines whether the automatic adjustment function of the apparatus 200 is enabled. The automatic adjustment function of the apparatus 200 can be enabled via pressing a specific key on the apparatus 200.

In step S306, the transmitter 22 generates and transmits the outputted signal. At the time of transmitting the outputted signal, the timer 28 starts to measure the time from transmitting the outputted signal to receiving the reflected signal that has the different frequency from the outputted signal

In step S308, the receiver 24 receives the reflected signal reflected back from the object.

In step S310, the detector 26 measures the reflected signal received by the receiver 24 to determine whether the reflected frequency is different from the outputted frequency. If the reflected frequency is not different from the outputted frequency, the procedure proceeds to step 312.

In step S312, a determination is made as to whether a predetermined period for receiving the reflected signal has elapsed. If the predetermined period has elapsed, the procedure goes back to step 306 to transmit the outputted signal again. If the predetermined period has not elapsed, the procedure goes back to step 308 to receive the reflected signal. That is, the predetermined period is used for setting a time interval between each time of transmitting the outputted signal.

If in step 310, the reflected frequency is different from the outputted frequency, the procedure proceeds to step 314. In step S314, the time Δt from transmitting the outputted signal to receiving the reflected signal is transmitted to the distance calculating unit 31.

In step S316, the distance calculating unit 31 calculates the distance S between the user 100 and the apparatus 200 based on the time Δt. The distance S is calculated by the following formula:

S=V*Δt/2

wherein V is the transmitting speed of the ultrasonic wave.

In step S318, the controller 32 receives the distance S calculated by the distance calculating unit 31 and searches the corresponding sound volume value based on the distance S.

In step S320, the controller 32 determines whether the corresponding sound volume value equals to the current sound volume value. If the corresponding sound volume value is not equal to the current sound volume value, the controller 32 generates the volume adjustment signal based on the corresponding sound volume value and transmits the volume adjustment signal to the adjust unit 34.

In step S322, the adjust unit 34 receives the volume adjustment signal and adjusts the sound volume based on the volume adjustment signal.

In step S324, a determination is made as to whether the predetermined period has elapsed. That is, it is determined whether the time interval between each time of transmitting the outputted signal has elapsed. If so, the procedure goes back to step 306 to transmit the outputted signal again. If the predetermined period has not elapsed, the procedure goes back to step 324 to wait until the predetermined period has elapsed.

If in step 320, the corresponding sound volume value equals to the current sound volume value, the controller 32 keeps the current sound volume value unchanged and the procedure proceeds straightly to step 324.

According to the method described above, the sound volume is adjusted according to the distance between the user 100 and the apparatus 200, thus the sound volume is adjusted automatically to achieve a best listening affect for the user 100.

In another preferred embodiment, it is not need to calculate the distance between the user 100 and the apparatus 200. The sound volume can be adjusted according to the time from transmitting the outputted signal to receiving the reflected signal having the different frequency as well. That is, the time can be used to correspond to the sound volume value directly.

The embodiments described herein are merely illustrative of the principles of the present invention. Other arrangements and advantages may be devised by those skilled in the art without departing from the spirit and scope of the present invention. Accordingly, the present invention should be deemed not to be limited to the above detailed description, but rather by the spirit and scope of the claims that follow, and their equivalents.

What is claimed is:

1. An apparatus for adjusting a sound volume, comprising:
a transmitter for transmitting an ultrasonic signal;
a receiver for receiving a reflected ultrasonic signal reflected back from an object;
a timer for measuring a time from transmitting the ultrasonic signal to receiving the reflected ultrasonic signal that has a different frequency from the ultrasonic signal;
a distance calculating unit for calculating a distance between the object and the apparatus based on the time; and
an adjust unit for adjusting the sound volume based on the distance.

2. The apparatus as claimed in claim 1, further comprising a detector for determining whether there is the frequency difference between the ultrasonic signal and the reflected ultrasonic signal.

3. The apparatus as claimed in claim 1, further comprising a storage unit for storing a sound volume value corresponding to the distance.

4. The apparatus as claimed in claim 3, further comprising a controller for searching the sound volume value according to the distance and transmitting a volume adjustment signal to the adjust unit based on the sound volume value.

5. The apparatus as claimed in claim 4, wherein the adjust unit is further configured for receiving an audio signal and adjusting the sound volume of the audio signal based on the volume adjustment signal.

6. The apparatus as claimed in claim 1, wherein the transmitter transmits the ultrasonic signal again if a predetermined period for receiving the reflected ultrasonic signal has elapsed.

7. An apparatus for adjusting a sound volume, comprising:
an ultrasonic transreceiver for transmitting an ultrasonic signal and receiving a reflected ultrasonic signal reflected back from an object; and
a volume module for adjusting the sound volume based on a time from transmitting the ultrasonic signal to receiving the reflected ultrasonic signal that has a different frequency from the ultrasonic signal.

8. The apparatus as claimed in claim 7, wherein the ultrasonic transreceiver comprises a transmitter for transmitting the ultrasonic signal.

9. The apparatus as claimed in claim 7, wherein the ultrasonic transreceiver further comprises a receiver for receiving the reflected ultrasonic signal.

10. The apparatus as claimed in claim 7, wherein the ultrasonic transreceiver further comprises a detector for measuring the different frequency.

11. The apparatus as claimed in claim 7, wherein the ultrasonic transreceiver further comprises a timer for measuring the time.

12. The apparatus as claimed in claim 10, wherein the volume module comprises a distance calculating unit for calculating a distance between the object and the apparatus based on the time, and an adjust unit for adjusting the sound volume based on the distance.

13. The apparatus as claimed in claim 12, wherein the volume module further comprises a storage unit for storing a sound volume value corresponding to the distance.

14. The apparatus as claimed in claim 13, wherein the volume module further comprises a controller for searching the sound volume value according to the distance and transmitting a volume adjustment signal to the adjust unit based on the sound volume value.

15. The apparatus as claimed in claim 14, wherein the adjust unit is further configured for receiving an audio signal and adjusting the sound volume of the audio signal based on the volume adjustment signal.

16. The apparatus as claimed in claim 7, wherein the ultrasonic transreceiver transmits the ultrasonic signal again if a predetermined period for receiving the reflected ultrasonic signal has elapsed.

17. A method for adjusting a sound volume of an apparatus, comprising:
transmitting an ultrasonic signal;
receiving a reflected ultrasonic signal reflected back from an object;
determining whether there is a frequency difference between the ultrasonic signal and the reflected ultrasonic signal;
measuring a time from transmitting the ultrasonic signal to receiving the reflected ultrasonic signal if there is the frequency difference between the ultrasonic signal and the reflected ultrasonic signal; and
adjusting the sound volume based on the time.

18. The method as claimed in claim 17, further comprising:
calculating a distance between the object and the apparatus based on the time; and
adjusting the sound volume based on the distance.

19. The method as claimed in claim 17, further comprising:
searching a sound volume value based on the distance;
generating a volume adjustment signal based on the sound volume value; and
adjusting the sound volume according to the volume adjustment signal.

20. The method as claimed in claim 17, further comprising: transmitting the ultrasonic signal again if a predetermined period for receiving the reflected ultrasonic signal has elapsed.
